(19) United States
(12) Patent Application Publication
(10) Pub. No.: US 2017/0248639 A1
(43) Pub. Date: Aug. 31, 2017

(54) SELF-PHASING ELECTRIC METER AND AUTOMATION SYSTEM

(71) Applicant: Siemens Industry, Inc., Alpharetta, GA (US)

(72) Inventors: Tyrell Craig Vaughn, Manchaca, TX (US); Joe Wallace White, Austin, TX (US)

(73) Assignee: Siemens Industry, Inc., Alpharetta, GA (US)

(21) Appl. No.: 15/055,082

(22) Filed: Feb. 26, 2016

(51) Int. Cl. G01R 21/00; G01R 29/18; G01R 21/06

(52) U.S. Cl. CPC G01R 21/006; G01R 21/06; G01R 29/18

(57) ABSTRACT

Building automation systems, energy meters, and associated methods. A method includes receiving a plurality of voltage inputs and a plurality of current inputs from a multiphase power source. The method includes selecting a first voltage input from the plurality of voltage inputs. The method includes performing a signed power factor computation between respective pairs of the first voltage input and each of the plurality of current inputs. The method includes identifying a pair with a greatest positive power factor value. The method includes designating the identified pair with the greatest positive power factor value as an associated phase pair.

### TECHNICAL FIELD

The present disclosure is directed, in general, to building automation systems and, more particularly, to systems and methods for automatic phasing in electric meters and other devices.

### BACKGROUND OF THE DISCLOSURE

Building automation systems encompass a wide variety of systems that aid in the monitoring and control of various aspects of building operation. Building automation systems include security systems, fire safety systems, lighting systems, and HVAC systems. The elements of a building automation system are widely dispersed throughout a facility. For example, an HVAC system may include temperature sensors and ventilation damper controls, as well as other elements, that are located in virtually every area of a facility. These building automation systems typically have one or more centralized control stations from which system data may be monitored and various aspects of system operation may be controlled and/or monitored.

To allow for monitoring and control of the dispersed control system elements, building automation systems often employ multi-level communication networks to communicate operational and/or alarm information between operating elements, such as sensors and actuators, and the centralized control station. One example of a building automation system is the Site Controls Controller, available from Siemens Industry, Inc. Building Technologies Division of Buffalo Grove, Ill. (“Siemens”). In this system, several control stations connected via an Ethernet or another type of network may be distributed throughout one or more building locations, each having the ability to monitor and control system operation.

In building automation systems and other systems that use polyphase electric power, it can be important to effectively measure and control electric power usage. Polyphase electric meters, in existing systems, can be difficult to correctly install and use when the phasing of the electric power is not known. Improved systems are desirable.

### SUMMARY OF THE DISCLOSURE

This disclosure describes building automation systems, energy meters, and associated methods. A method includes receiving a plurality of voltage inputs and a plurality of current inputs from a multiphase power source. The method includes selecting a first voltage input from the plurality of voltage inputs. The method includes performing a signed power factor computation between respective pairs of the first voltage input and each of the plurality of current inputs. The method includes identifying a pair with a greatest positive power factor value. The method includes designating the identified pair with the greatest positive power factor value as an associated phase pair.

Other technical features may be readily apparent to one skilled in the art from the following figures, descriptions, and claims.

Before undertaking the DETAILED DESCRIPTION below, it may be advantageous to set forth definitions of certain words or phrases used throughout this patent document: the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 illustrates a block diagram of a building automation system in which the energy efficiency of a heating, ventilation, and air conditioning (HVAC) system may be improved in accordance with the present disclosure;

FIG. 2 illustrates details of one of the field panels of FIG. 1 in accordance with the present disclosure;

FIG. 3 illustrates details of one of the field controllers of FIG. 1 in accordance with the present disclosure;

FIGS. 4 and 5 illustrate block diagrams of energy meters in accordance with disclosed embodiments; and

FIG. 6 illustrates a flowchart of a process in accordance with disclosed embodiments.

### DETAILED DESCRIPTION

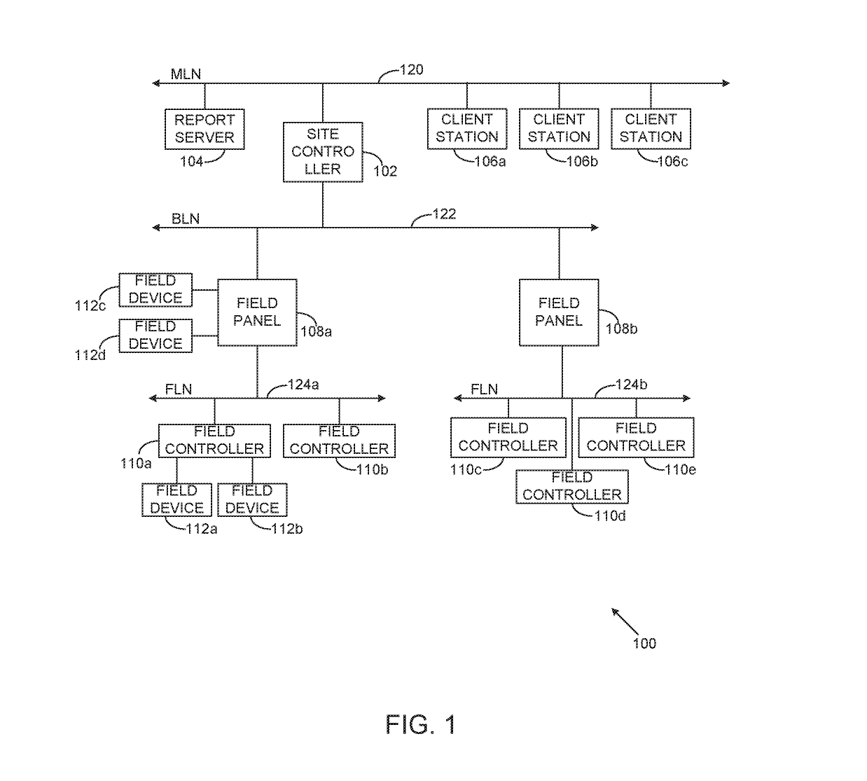

FIGS. 1 through 6, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device or system.

The installation of a 3-phase energy meter, whether in a building automation system, as a stand-alone meter, or otherwise, requires that a current sensing device needs to be placed on each conductor of the 3 phase power system. Normally, current transfomers (CTs) or Rogowski Coils are used for this purpose; this document will refer generically to CTs, but this term is intended to include any equivalent current sensing device. In addition, a voltage sense lead needs to be connected to each leg of the 3-phase power system. From the mathematical operations performed by the energy meter, energy usage (or generation), energy demand, phase voltages, phase currents, power factor and other parameters can be determined.

To correctly determine these values, it is important that the voltage sense and its corresponding current sense must be on the same phase of the 3-phase power system. Currently, this installation is done manually and verified by inspection, which can be time consuming and inefficient. In cases where the voltage pickup points and the current pickup points are separated physically, manual phasing becomes more of a trial-and-error type of installation. Automatic phasing as disclosed herein can eliminate the manual steps of determining correct meter phasing. Energy meter manufacturers as well as competitive energy management system suppliers have similar need and would benefit from such a feature.

Disclosed embodiments include systems and methods for automatic determination and configuration of correct phasing in a 3-phase or other polyphase electrical systems.

FIG. 1 illustrates a block diagram of a building automation system 100 in which automatic phasing of electrical metering equipment and other equipment can be implemented. The building automation system 100 can be, for example, an environmental control system configured to control at least one of a plurality of environmental parameters within a building, such as temperature, humidity, lighting and/or the like. For example, for a particular embodiment, the building automation system 100 may comprise the Site Controls Controller building automation system that allows the setting and/or changing of various controls of the system. While a brief description of the building automation system 100 is provided below, it will be understood that the building automation system 100 described herein is only one example of a particular form or configuration for a building automation system and that the system 100 may be implemented in any other suitable manner without departing from the scope of this disclosure.

For the illustrated embodiment, the building automation system 100 comprises a site controller 102, a report server 104, a plurality of client stations 106a-c, a plurality of field panels 108a-b, a plurality of field controllers 110a-e and a plurality of field devices 112a-d. Although illustrated with three client stations 106, two field panels 108, five field controllers 110 and four field devices 112, it will be understood that the system 100 may comprise any suitable number of any of these components 106, 108, 110 and 112 based on the particular configuration for a particular building. Note that this exemplary architecture is not intended to be limiting to the disclosed embodiments. For example, a field panel 108 and a field controller 110 can be integrated into a single entity in specific implementations.

The site controller 102, which may comprise a computer or a general-purpose processor, is configured to provide overall control and monitoring of the building automation system 100. The site controller 102 may operate as a data server that is capable of exchanging data with various elements of the system 100. As such, the site controller 102 may allow access to system data by various applications that may be executed on the site controller 102 or other supervisory computers (not shown in FIG. 1).

For example, the site controller 102 may be capable of communicating with other supervisory computers, Internet gateways, or other gateways to other external devices, as well as to additional network managers (which in turn may connect to more subsystems via additional low-level data networks) by way of a management level network (MLN) 120. The site controller 102 may use the MLN 120 to exchange system data with other elements on the MLN 120, such as the report server 104 and one or more client stations 106. The report server 104 may be configured to generate reports regarding various aspects of the system 100. Each client station 106 may be configured to communicate with the system 100 to receive information from and/or provide modifications to the system 100 in any suitable manner. The MLN 120 may comprise an Ethernet or similar wired network and may employ TCP/IP, BACnet and/or other protocols that support high-speed data communications.

The site controller 102 may also be configured to accept modifications and/or other input from a user. This may be accomplished via a user interface of the site controller 102 or any other user interface that may be configured to communicate with the site controller 102 through any suitable network or connection. The user interface may include a keyboard, touchscreen, mouse, or other interface components. The site controller 102 is configured to, among other things, affect or change operational data of the field panels 108, as well as other components of the system 100. The site controller 102 may use a building level network (BLN) 122 to exchange system data with other elements on the BLN 122, such as the field panels 108.

Each field panel 108 may comprise a general-purpose processor and is configured to use the data and/or instructions from the site controller 102 to provide control of its one or more corresponding field controllers 110. While the site controller 102 is generally used to make modifications to one or more of the various components of the building automation system 100, a field panel 108 may also be able to provide certain modifications to one or more parameters of the system 100. Each field panel 108 may use a field level network (FLN) 124 to exchange system data with other elements on the FLN 124, such as a subset of the field controllers 110 coupled to the field panel 108.

Each field controller 110 may comprise a general-purpose processor and may correspond to one of a plurality of localized, standard building automation subsystems, such as building space temperature control subsystems, lighting control subsystems, or the like. For a particular embodiment, the field controllers 110 may comprise the model TEC (Terminal Equipment Controller) available from Siemens. However, it will be understood that the field controllers 110 may comprise any other suitable type of controllers without departing from the scope of the present invention.

To carry out control of its corresponding subsystem, each field controller 110 may be coupled to one or more field devices 112. Each field controller 110 is configured to use the data and/or instructions from its corresponding field panel 108 to provide control of its one or more corresponding field devices 112. For some embodiments, some of the field controllers 110 may control their subsystems based on sensed conditions and desired set point conditions. For these embodiments, these field controllers 110 may be configured to control the operation of one or more field devices 112 to attempt to bring the sensed condition to the desired set point condition. It is noted that in the system 100, information from the field devices 112 may be shared between the field controllers 110, the field panels 108, the site controller 102 and/or any other elements on or connected to the system 100.

In order to facilitate the sharing of information between subsystems, groups of subsystems may be organized into an FLN 124. For example, the subsystems corresponding to the field controllers 110a and 110b may be coupled to the field panel 108a to form the FLN 124a. The FLNs 124 may each comprise a low-level data network that may employ any suitable proprietary or open protocol.

Each field device 112 may be configured to measure, monitor and/or control various parameters of the building automation system 100. Examples of field devices 112 include lights, thermostats, temperature sensors, fans, damper actuators, heaters, chillers, alarms, HVAC devices, and numerous other types of field devices. The field devices 112 may be capable of receiving control signals from and/or sending signals to the field controllers 110, the field panels 108 and/or the site controller 102 of the building automation system 100. Accordingly, the building automation system 100 is able to control various aspects of building operation by controlling and monitoring the field devices 112.

As illustrated in FIG. 1, any of the field panels 108, such as the field panel 108a, may be directly coupled to one or more field devices 112, such as the field devices 112c and 112d. For this type of embodiment, the field panel 108a may be configured to provide direct control of the field devices 112c and 112d instead of control via one of the field controllers 110a or 110b. Therefore, for this embodiment, the functions of a field controller 110 for one or more particular subsystems may be provided by a field panel 108 without the need for a field controller 110.

As described in more detail below, a field device such as field device 112c can be implemented as a self-phasing electric meter as described herein, and can be connected, for example, to a communication module in a field controller.

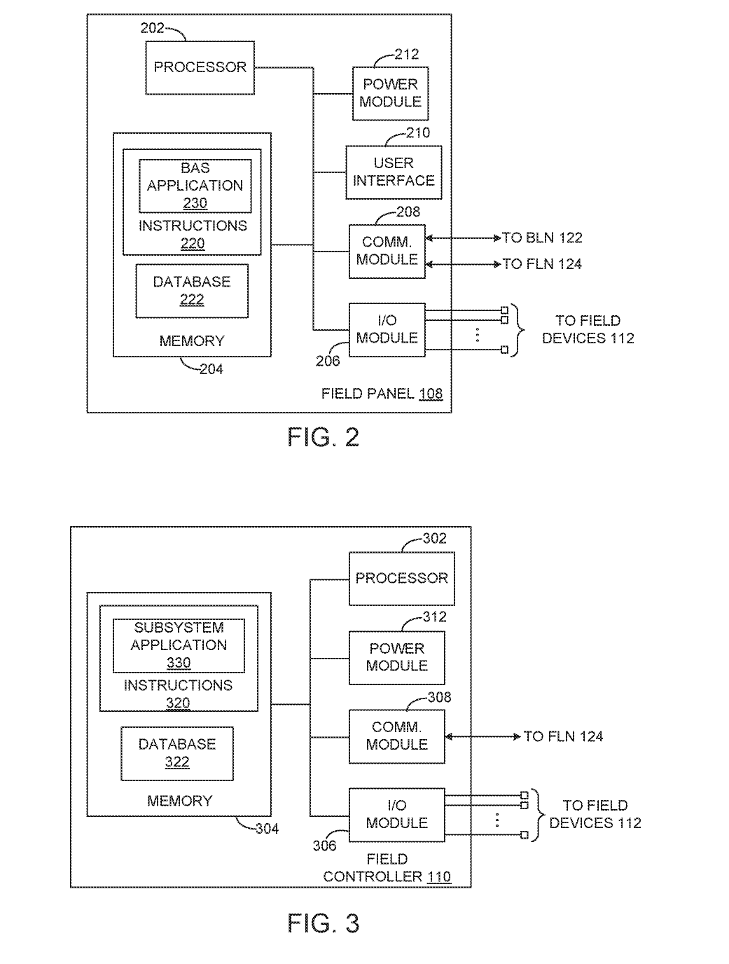

FIG. 2 illustrates details of one of the field panels 108 in accordance with the present disclosure. For this particular embodiment, the field panel 108 comprises a processor 202, a memory 204, an input/output (I/O) module 206, a communication module 208, a user interface 210 and a power module 212. The memory 204 comprises any suitable data store capable of storing data, such as instructions 220 and a database 222. It will be understood that the field panel 108 may be implemented in any other suitable manner without departing from the scope of this disclosure.

The processor 202 is configured to operate the field panel 108. Thus, the processor 202 may be coupled to the other components 204, 206, 208, 210 and 212 of the field panel 108. The processor 202 may be configured to execute program instructions or programming software or firmware stored in the instructions 220 of the memory 204, such as building automation system (BAS) application software 230. In addition to storing the instructions 220, the memory 204 may also store other data for use by the system 100 in the database 222, such as various records and configuration files, graphical views and/or other information.

Execution of the BAS application 230 by the processor 202 may result in control signals being sent to any field devices 112 that may be coupled to the field panel 108 via the I/O module 206 of the field panel 108. Execution of the BAS application 230 may also result in the processor 202 receiving status signals and/or other data signals from field devices 112 coupled to the field panel 108 and storage of associated data in the memory 204. In one embodiment, the BAS application 230 may be provided by the Site Controls Controller software commercially available from Siemens Industry, Inc. However, it will be understood that the BAS application 230 may comprise any other suitable BAS control software.

The I/O module 206 may comprise one or more input/output circuits that are configured to communicate directly with field devices 112. Thus, for some embodiments, the I/O module 206 comprises analog input circuitry for receiving analog signals and analog output circuitry for providing analog signals.

The communication module 208 is configured to provide communication with the site controller 102, other field panels 108 and other components on the BLN 122. The communication module 208 is also configured to provide communication to the field controllers 110, as well as other components on the FLN 124 that is associated with the field panel 108. Thus, the communication module 208 may comprise a first port that may be coupled to the BLN 122 and a second port that may be coupled to the FLN 124. Each of the ports may include an RS-485 standard port circuit or other suitable port circuitry.

The field panel 108 may be capable of being accessed locally via the interactive user interface 210. A user may control the collection of data from field devices 112 through the user interface 210. The user interface 210 of the field panel 108 may include devices that display data and receive input data. These devices may be permanently affixed to the field panel 108 or portable and moveable. For some embodiments, the user interface 210 may comprise an LCD-type screen or the like and a keypad. The user interface 210 may be configured to both alter and show information regarding the field panel 108, such as status information and/or other data pertaining to the operation of, function of and/or modifications to the field panel 108.

The power module 212 may be configured to supply power to the components of the field panel 108. The power module 212 may operate on standard 120 volt AC electricity, other AC voltages or DC power supplied by a battery or batteries. As described in more detail below, a field device such as a field device 112 can be implemented as a self-phasing electric meter as described herein and interact with the field panel 108.

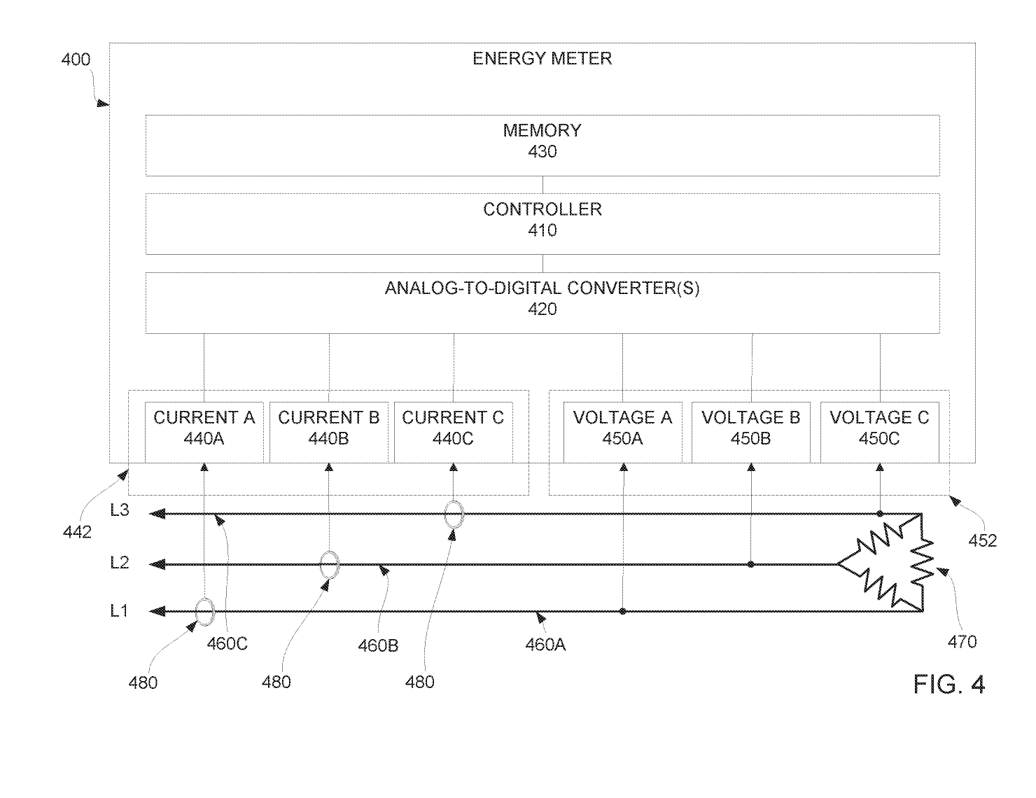

FIG. 3 illustrates details of one of the field controllers 110 in accordance with the present disclosure. For this particular embodiment, the field controller 110 comprises a processor 302, a memory 304, an input/output (I/O) module 306, a communication module 308 and a power module 312. For some embodiments, the field controller 110 may also comprise a user interface (not shown in FIG. 3) that is configured to alter and/or show information regarding the field controller 110. The memory 304 comprises any suitable data store capable of storing data, such as instructions 320 and a database 322. It will be understood that the field controller 110 may be implemented in any other suitable manner without departing from the scope of this disclosure. For some embodiments, the field controller 110 may be positioned in, or in close proximity to, a room of the building where temperature or another environmental parameter associated with the subsystem may be controlled with the field controller 110.

The processor 302 is configured to operate the field controller 110. Thus, the processor 302 may be coupled to the other components 304, 306, 308 and 312 of the field controller 110. The processor 302 may be configured to execute program instructions or programming software or firmware stored in the instructions 320 of the memory 304, such as subsystem application software 330. For a particular example, the subsystem application 330 may comprise a temperature control application that is configured to control and process data from all components of a temperature control subsystem, such as a temperature sensor, a damper actuator, fans, and various other field devices. In addition to storing the instructions 320, the memory 304 may also store other data for use by the subsystem in the database 322, such as various configuration files and/or other information.

Execution of the subsystem application 330 by the processor 302 may result in control signals being sent to any field devices 112 that may be coupled to the field controller 110 via the I/O module 306 of the field controller 110. Execution of the subsystem application 330 may also result in the processor 302 receiving status signals and/or other data signals from field devices 112 coupled to the field controller 110 and storage of associated data in the memory 304.

The I/O module 306 may comprise one or more input/output circuits that are configured to communicate directly with field devices 112. Thus, for some embodiments, the I/O module 306 comprises analog input circuitry for receiving analog signals and analog output circuitry for providing analog signals.

The communication module 308 is configured to provide communication with the field panel 108 corresponding to the field controller 110 and other components on the FLN 124, such as other field controllers 110. Thus, the communication module 308 may comprise a port that may be coupled to the FLN 124. The port may include an RS-485 standard port circuit or other suitable port circuitry.

The power module 312 may be configured to supply power to the components of the field controller 110. The power module 312 may operate on standard 120 volt AC electricity, other AC voltages, or DC power supplied by a battery or batteries.

As described in more detail below, a field device such as a field device 112 can be implemented as a self-phasing electric meter as described herein and can interact with the field controller 110.

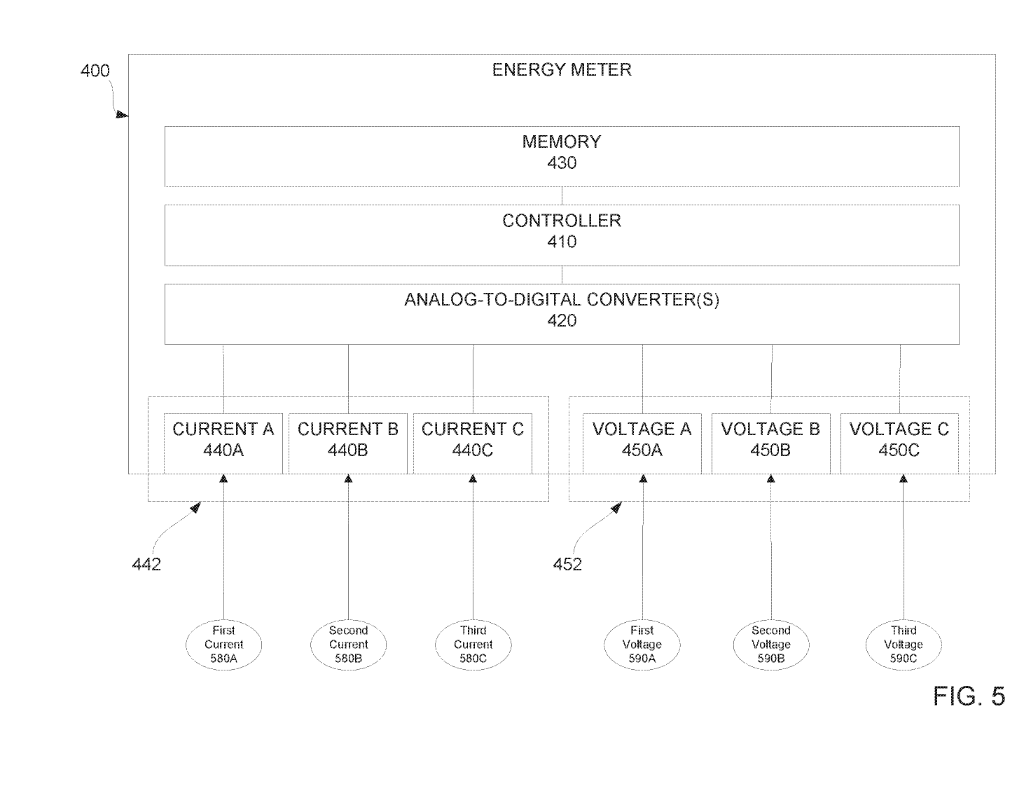

FIG. 4 illustrates a block diagram of an energy meter 400 in accordance with disclosed embodiments, that can be used as a field device 112. Of course, those of skill in the art will recognize that other metering, control, or other functions can be implemented in energy meter 400 in addition to those described herein.

In this example, energy meter 400 includes a controller 410, one or more analog-to-digital converters (ADCs) 420, and a memory 230. Controller 410 is connected to interact with memory 430 and ADCs 420. Energy meter 400 also includes current inputs 440 (denoted as current A 440A, current B 440B, and current C 440C) at current input connections 442 and voltage inputs 450 (denoted as voltage A 450A, voltage B 450B, and voltage C 450C) at voltage input connections 452. These inputs may also be referred to generically as first, second, and third current or voltage inputs, which receive first, second, and third currents or voltages. ADCs 420 convert the current and voltage inputs into digital values that can be read and processed by controller 410, as understood by those of skill in the art, while memory 430 can include executable instructions for the energy meter 400, voltage and current values for each of the inputs, and other data useable by controller 410.

FIG. 4 illustrates an exemplary “ideal” connection, where three-phase power source 470 has specific known line outputs 460 denoted as L1 460A, L2 460B, and L3 460C. Each of these line outputs operates on a different phase. In this example, L1 460A is directly connected to voltage A input 450A, and via a CT 480 to current A input 440A. Similarly, L2 460B is directly connected to voltage B input 450B, and via a CT 480 to current B input 440B, and L3 460C is directly connected to voltage C input 450C, and via a CT 480 to current C input 440C.

When the connections between the power source 470 and the energy meter 400 are known and correctly made, as illustrated, then energy metering functions can be performed accurately, since each voltage and current correspond to the same line output from the power sources 470 and are necessarily in the same phase (that is, voltage A 450A and current A 440A are both known to be connected to L1 460A, so metering functions performed for L1 460A, based on voltage A 450A and current A 440A, are accurate).

However, in many practical implementations, the current and voltage inputs are unlabeled and unknown, so installation and operation can be inefficient, inaccurate, and time consuming while an operator identifies and verifies each of the connections.

FIG. 5 illustrates another block diagram of an energy meter 400 in accordance with disclosed embodiments, that can be used as a field device 112, where like elements numbers indicate the same elements as illustrated in FIG. 4. However, in FIG. 5, the current inputs 580 are simply denoted as first current input 580A, second current input 580B, and third current input 580C. Similarly, the voltage inputs 590 are simply denoted as first voltage input input, second voltage input 590B, and third voltage input 590C. In this example, while each of the current and voltage inputs are from one or another of the line inputs, it is unknown which current corresponds to which voltage (or to which line input). FIG. 5 illustrates the case of a typical installation, where the actual current and voltage inputs are unlabeled and unknown, and so metering functions that must use corresponding voltages and currents (that is, voltages and currents from the same line input) cannot be properly performed. Note that the terms “input voltage” and “voltage input” may be used interchangeably herein, as may “input current” and “current input.” Note further that commonly-labeled elements of FIG. 5 correspond to the elements of FIG. 4, and are not necessarily re-described here.

Disclosed embodiments reduce installation time of an energy meter 400 and ensures that the readings are valid. According to disclosed embodiments, the controller 410 can identify which current input is associated each voltage input by determining which current and voltage are operating on the same phase. The controller 410 can then associate or “match” the given phase current input with the corresponding phase voltage input. Once these associations are known, the energy meter 400 can thereafter perform metering functions using the respective associated current and voltage inputs.

Note that, while the description and examples herein are specifically for a three-phase system, the same principles and processes can be applied to any multiphase electrical system, and the claims are intended to apply to any multiphase system unless expressly otherwise limited.

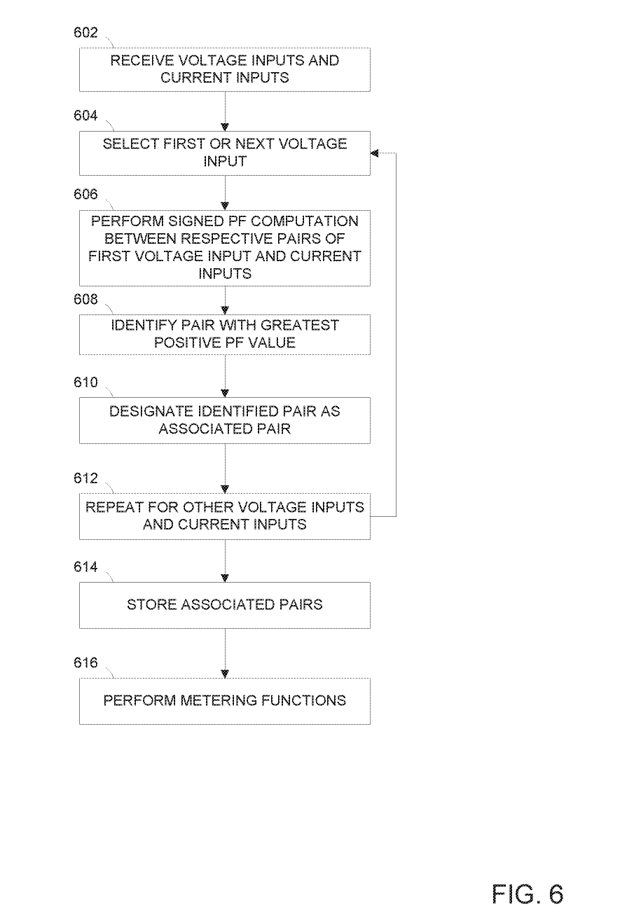

FIG. 6 illustrates a flowchart of a process in accordance with disclosed embodiments that can be performed, for example, by an energy meter 400 as described herein. In such a process, the energy meter will treat the multiphase power system as if it were multiple single phase systems. For ease of reference, each phase is arbitrarily labeled A, B or C in a 3 phase power system. The meter also has voltage inputs for A, B and C phases as well as current inputs for A, B, and C phases. The labeling is arbitrary for both the power system and the meter. As described below, these inputs will be referred to as first, second, and third voltage inputs, and first, second, and third current inputs. Each of the voltage inputs and current inputs are connected to a respective phase voltage or phase current of the multiphase system, but the phase of each of the voltage inputs and current inputs is unknown.

The energy meter 400 receives a plurality of voltage inputs and a plurality of current inputs from a multiphase power source (602). These can be whatever voltage and current input connections are made when the energy meter 400 is installed and the voltage and current inputs from the multiphase power source are applied.

The energy meter 400 selects a first voltage input from the plurality of voltage input (604).

The energy meter 400 performs a signed power factor computation between respective pairs of the first voltage input and each of the plurality of current inputs (606). It is understood that such a computation can be performed using a voltage value for the voltage input and current values for each of the current inputs, such as may be produced by ADCs 420. As part of this step, the energy meter 400 can save each of the computed power factors in memory 430.

For example, the pair of the first voltage input to the first current input will have an indicated power factor (pf) of x, the pair of the first voltage input to the second current input will have an indicated pf of y, and the pair of the first voltage input to the third current input will have an indicated pf of z.

The energy meter 400 identifies the pair that has the greatest positive pf value (608). For example, if the pair of the first voltage input to the second current input has an indicated pf of y, and y is greater than x or z in the example above, then the energy meter identifies the pair of the first voltage input to the second current input.

The energy meter 400 designates the identified pair with the greatest positive pf value as an associated phase pair for the first voltage input and associated first phase (610).

The energy meter 400 repeats the selecting, power factor computation, identification processes for each of the other voltage inputs with respect to each of the other current inputs (612). Once a voltage input and current input has been designated as an associated phase pair, that voltage input and current input is no longer part of the iteration. In this example, after the first pass, the first voltage input and second current input is not included in the electing, power factor computation, identification processes for the second pass. In this way, the processes are repeated for each of the voltage inputs and current inputs that are not designated as an associated phase pair until each voltage input and each current input are part of an associated phase pair.

The energy meter 400 stores the associated phase pairs in the memory 430 (614). These associated phase pairs reflect the correct phasing for the connections to the multiphase power source.

The energy meter 400 performs metering functions using the respective associated pair of voltage inputs and current inputs (616).

Preferably, in disclosed embodiments, the current levels in each of the phases must be at or above the minimum value specified for the CTs used. Preferably, the installation is of the type where power factors in the range of 0.6 to 1 are expected.

In various embodiments, the processes described herein can be initiated in various means, such as by the push of a button or from an external command via a network connection to the energy meter 400.

Those of skill in the art will recognize that, unless specifically indicated or required by the sequence of operations, certain steps in the processes described above may be omitted, combined, performed concurrently or sequentially, or performed in a different order. Processes and elements of different exemplary embodiments above can be combined within the scope of this disclosure.

Those skilled in the art will recognize that, for simplicity and clarity, the full structure and operation of all data processing systems or building automation systems suitable for use with the present disclosure is not being depicted or described herein. Instead, only so much of a data processing system as is unique to the present disclosure or necessary for an understanding of the present disclosure is depicted and described. The remainder of the construction and operation of the systems disclosed herein may conform to any of the various current implementations and practices known in the art.

It is important to note that while the disclosure includes a description in the context of a fully functional system, those skilled in the art will appreciate that at least portions of the mechanism of the present disclosure are capable of being distributed in the form of instructions contained within a machine-usable, computer-usable, or computer-readable medium in any of a variety of forms, and that the present disclosure applies equally regardless of the particular type of instruction or signal bearing medium or storage medium utilized to actually carry out the distribution. Examples of machine usable/readable or computer usable/readable media include: nonvolatile, hard-coded type media such as read-only memories (ROMs) or electrically erasable programmable read-only memories (EEPROMs), and user-recordable type media such as floppy disks, hard disk drives and compact disc read-only memories (CD-ROMs) or digital versatile discs (DVDs).

While this disclosure has described certain embodiments and generally associated methods, alterations and permutations of these embodiments and methods will be apparent to those skilled in the art. Accordingly, the examples of various embodiments described above do not define or constrain this disclosure. Other changes, substitutions, and alterations are also possible without departing from the spirit and scope of this disclosure, as defined by the following claims.

What is claimed is:

1. A method, comprising:
receiving a plurality of voltage inputs and a plurality of current inputs by an energy meter and from a multiphase power source;
selecting a first voltage input from the plurality of voltage inputs by the energy meter;
performing a signed power factor computation between respective pairs of the first voltage input and each of the plurality of current inputs by the energy meter;
identifying a pair with a greatest positive power factor value by the energy meter; and
designating the identified pair with the greatest positive power factor value as an associated phase pair by the energy meter.

2. The method of claim 1, wherein the selecting, performing, identifying, and designating processes are repeated for each of the voltage inputs and current inputs that are not designated as an associated phase pair.

3. The method of claim 1, wherein the signed power factor computation is performed using a voltage value for the first voltage input and current values for each of the current inputs.

4. The method of claim 1, wherein the energy meter also stores each of the power factors.

5. The method of claim 1, wherein the energy meter stores the associated phase pair.

6. The method of claim 1, wherein the energy meter thereafter performs metering functions using the associated phase pair.

7. The method of claim 1, wherein the method is performed in response to receiving an external command via a network connection to the energy meter.

8. An energy meter, comprising:
a plurality of voltage input connections and a plurality of current input connections;
a controller operatively connected to the voltage input connections and the current input connections; and
a memory operatively connected to the controller, wherein the energy meter is configured to:
receive a plurality of voltage inputs at the voltage input connections and a plurality of current inputs at the current input connections, from a multiphase power source;
select a first voltage input from the plurality of voltage inputs;
perform a signed power factor computation between respective pairs of the first voltage input and each of the plurality of current inputs;
identify a pair with a greatest positive power factor value; and
designate the identified pair with the greatest positive power factor value as an associated phase pair.

9. The energy meter of claim 8, wherein the selecting, performing, identifying, and designating processes are repeated for each of the voltage inputs and current inputs that are not designated as an associated phase pair.

10. The energy meter of claim 8, wherein the signed power factor computation is performed using a voltage value for the first voltage input and current values for each of the current inputs.

11. The energy meter of claim 8, wherein the energy meter also stores each of the power factors.

12. The energy meter of claim 8, wherein the energy meter stores the associated phase pair.

13. The energy meter of claim 8, wherein the energy meter thereafter performs metering functions using the associated phase pair.

14. The energy meter of claim 8, wherein the energy meter is configured to perform the processes in response to receiving an external command via a network connection to the energy meter.

15. A building automation system, comprising:
a site controller; and
an energy meter having a plurality of voltage input connections and a plurality of current input connections, a controller operatively connected to the voltage input connections and the current input connections, and a memory operatively connected to the controller, wherein the energy meter is configured to:
receive a plurality of voltage inputs at the voltage input connections and a plurality of current inputs at the current input connections, from a multiphase power source;
select a first voltage input from the plurality of voltage inputs;
perform a signed power factor computation between respective pairs of the first voltage input and each of the plurality of current inputs;
identify a pair with a greatest positive power factor value; and
designate the identified pair with the greatest positive power factor value as an associated phase pair.

16. The building automation system of claim 15, wherein the selecting, performing, identifying, and designating processes are repeated for each of the voltage inputs and current inputs that are not designated as an associated phase pair.

17. The building automation system of claim 15, wherein the signed power factor computation is performed using a voltage value for the first voltage input and current values for each of the current inputs.

18. The building automation system of claim 15, wherein the energy meter also stores each of the power factors.

19. The building automation system of claim 15, wherein the energy meter stores the associated phase pair.

20. The building automation system of claim 15, wherein the energy meter thereafter performs metering functions using the associated phase pair.
